(19) United States
(12) Patent Application Publication
(10) Pub. No.: US 2014/0055929 A1
(43) Pub. Date: Feb. 27, 2014

(54) STRUCTURE, DISPLAY APPARATUS AND METHOD OF MOLDING STRUCTURE

(71) Applicant: Sony Corporation, Tokyo (JP)

(72) Inventors: Hiroyasu Sato, Tokyo (JP); Takuya Toriumi, Kanagawa (JP)

(73) Assignee: SONY CORPORATION, Tokyo (JP)

(21) Appl. No.: 13/965,473

(22) Filed: Aug. 13, 2013

(30) Foreign Application Priority Data
Aug. 24, 2012 (JP) 2012-185690

(51) Int. Cl. H05K 7/18; B29C 47/00

(52) U.S. Cl. CPC H05K 7/18; B29C 47/003
USPC 361/679.01; 264/210.1; 428/130

(57) ABSTRACT

A structure in which a folding notch, which is open in a direction orthogonal to an extrusion direction, is formed on a molded product formed using profile extrusion, each portion of an open edge of the folding notch is formed as a first matching portion and a second matching portion which are separate or continuous in the extrusion direction, and the molded product is folded such that the first matching portion and the second matching portion face each other.

### BACKGROUND

The present disclosure relates to the technical field of a structure, a display apparatus and a method of molding the structure. Specifically, the present disclosure relates to the technical field of reducing the manufacturing cost and improving the design freedom by forming a molded product by using extrusion and then folding the molded product.

A display including a display surface on which an image is displayed is provided in a display apparatus of various electronic devices, such as a television receiver or a personal computer. For example, a diffuser plate, an optical sheet and the like are disposed on the rear face of the display, and the panel module includes the display, the diffuser plate, the optical sheet and the like.

A bezel is provided in such a display apparatus as a member which maintains the peripheral portion of the panel module. For example, the bezel is provided in a frame shape, includes a portion which extends in the horizontal direction and a portion which extends in the vertical direction, and is configured such that the portions are orthogonal to each other.

Such a structure of a non-linear shape such as a bezel is generally formed using injection molding which uses a molding die including a core mold and a cavity mold (for example, refer to Japanese Unexamined Patent Application Publication No. 2010-237474).

The formation of the structure such as a bezel using a molding die is performed by filling a cavity formed inside the molding die with a molten resin, and after cooling the molten resin, releasing the mold and pushing out the molded product using an ejector pin or the like.

### SUMMARY

However, in the formation of a structure using injection molding as disclosed in Japanese Unexamined Patent Application Publication No. 2010-237474, since the manufacturing cost of the molding die is high, the manufacturing cost of the structure to be formed also becomes high.

In addition, when the shape of the structure is modified, it is necessary to manufacture a molding die so as to include a cavity of a shape appropriate for the structure every time there is a modification, and there is also a problem in that the design freedom is poor.

Therefore, it is desirable to provide a structure, a display apparatus and a method of molding the structure according to an embodiment of the present disclosure which solve the above problems, decrease the manufacturing costs and increase the design freedom.

First, according to an embodiment of the present disclosure, there is provided a structure in which a folding notch, which is open in a direction orthogonal to an extrusion direction, is formed on a molded product formed using profile extrusion, each portion of an open edge of the folding notch is formed as a first matching portion and a second matching portion which are separate or continuous in the extrusion direction, and the molded product is folded such that the first matching portion and the second matching portion face each other.

Accordingly, in the structure, the structure is formed by folding the molded product formed using profile extrusion, and causing the first matching portion and the second matching portion to face each other.

Second, in the structure described above, it is desirable that the molded product be formed with a small opening in communication with the folding notch, and that both ends of the small opening in a circumferential direction be continuous with each end of the first matching portion and the second matching portion, respectively.

The molded product is formed with a small opening in communication with the folding notch and both ends of the small opening in the circumferential direction are continuous with each end of the first matching portion and the second matching portion, respectively. Therefore, a surface of the structure which is to protrude to the outside due to folding is positioned in the small opening.

Third, in the structure described above, it is desirable that a groove portion which extends in the extrusion direction be formed in the molded product, and that the small opening be formed in the groove portion.

The groove portion which extends in the extrusion direction is formed in the molded product, and the small opening is formed in the groove portion. Therefore, when the surface of the structure bulges, the bulge is present in the groove portion.

Fourth, in the structure described above, it is desirable that a periphery of the small opening be formed in a curved line shape.

There are no corner portions in the periphery of the small opening due to the periphery of the small opening being formed in a curved line shape. Therefore, stress is not apt to concentrate in the periphery of the small opening during the folding.

Fifth, in the structure described above, it is desirable that both the first matching portion and the second matching portion be formed in a straight line shape.

Since both the first matching portion and the second matching portion are formed in a straight line shape, it is easy to form the folding notch, the processing precision of the folding notch is high, and, when the first matching portion and the second matching portion face each other, a gap is not easily formed therebetween.

Sixth, in the structure described above, it is desirable that the first matching portion and the second matching portion be formed in a V-shape.

The first matching portion and the second matching portion are formed in a V-shape. Therefore, the formation of the folding notch is even easier, and the processing precision of the folding notch is also high.

Seventh, in the structure described above, it is desirable that a first face portion and a second face portion which each extend in the extrusion direction orthogonal to each other be provided, and that the folding notch be formed in the first face portion.

The first face portion and the second face portion which each extend in the extrusion direction orthogonal to each other are provided, and the folding notch is formed in the first face portion. Therefore, the structure includes orthogonal portions, and the folding notch is formed only in the first face portion.

Eighth, in the structure described above, it is desirable that a plurality of the folding notches be formed in the extrusion direction.

The plurality of the folding notches is formed in the extrusion direction. Therefore, it is possible to form the same number of folding locations as the number of folding notches.

According to another embodiment of the present disclosure, there is provided a display apparatus, including a panel module which includes a display on which an image is displayed, and a bezel which maintains a peripheral portion of the panel module, in which the bezel is formed from a molded product which is formed using profile extrusion so as to have a folding notch open in a direction orthogonal to an extrusion direction, each portion of an open edge of the folding notch is formed as a first matching portion and a second matching portion which are separate or continuous in the extrusion direction, and in which the molded product is folded such that the first matching portion and the second matching portion face each other, thereby forming the bezel.

Accordingly, in the display apparatus, the bezel is formed by folding the molded product formed using profile extrusion, and causing the first matching portion and the second matching portion to face each other.

According to still another embodiment of the present disclosure, there is provided a method of molding a structure, including forming a molded product using profile extrusion; forming a folding notch on the molded product, where the folding notch is open in a direction orthogonal to an extrusion direction and each portion of an open edge of the folding notch is a first matching portion and a second matching portion which are separate or continuous in the extrusion direction; and folding the molded product such that the first matching portion and the second matching portion face each other, thereby forming the structure.

Accordingly, in the method of molding the structure, the structure is formed by folding the molded product formed using profile extrusion, and causing the first matching portion and the second matching portion to face each other.

In the structure according to an embodiment of the present disclosure, a folding notch, which is open in a direction orthogonal to an extrusion direction, is formed on a molded product formed using profile extrusion, each portion of an open edge of the folding notch is formed as a first matching portion and a second matching portion which are separate or continuous in the extrusion direction, and the molded product is folded such that the first matching portion and the second matching portion face each other.

Accordingly, since the molded product configuring the structure is formed using extrusion and not injection molding, it is possible to reduce the manufacturing cost of the structure.

In addition, even when the shape of the structure is modified, it is not necessary to manufacture a new molding die appropriate for the structure, as is in the injection molding, and it is possible to improve the design freedom accordingly.

According to an embodiment of the present disclosure, the molded product is formed with a small opening in communication with the folding notch, and both ends of the small opening in a circumferential direction are continuous with each end of the first matching portion and the second matching portion, respectively.

Accordingly, the surface of the structure which is to protrude to the outside due to folding is positioned in the small opening, and it is possible to reduce the bulging of the surface of the structure.

According to an embodiment of the present disclosure, a groove portion which extends in the extrusion direction is formed in the molded product, and the small opening is formed in the groove portion.

Accordingly, even in a case in which the bulging of the surface of the structure occurs, the bulge is present in the groove portion, the state of the bulge of the surface of the structure is not obvious from the outside, and it is possible to improve the visual properties of the structure.

According to an embodiment of the present disclosure, the periphery of the small opening is formed in a curved line shape.

Accordingly, since there are no corner portions in the periphery of the small opening, stress is not apt to concentrate in the periphery of the small opening during the folding of each portion, and it is possible to prevent the occurrence of cracks in the structure.

According to an embodiment of the present disclosure, both the first matching portion and the second matching portion are formed in a straight line shape.

Accordingly, it is easy to form the folding notch, the processing precision of the folding notch is high, and, when the first matching portion and the second matching portion face each other, a gap is not easily formed therebetween. Therefore, it is possible to form the structure with a high molding precision.

According to an embodiment of the present disclosure, the first matching portion and the second matching portion are formed in a V-shape.

Accordingly, it is even easier to form the folding notch, the processing precision of the folding notch is high, and it is possible to form the structure with even higher molding precision.

According to an embodiment of the present disclosure, a first face portion and a second face portion which each extend in the extrusion direction orthogonal to each other are provided, and the folding notch is formed in the first face portion.

Accordingly, the structure includes orthogonal portions, the folding notch is formed only in the first face portion, and the notch or the like is not formed in the second face portion. Therefore, it is possible to secure high rigidity in the entirety of the structure.

According to an embodiment of the present disclosure, a plurality of the folding notches is formed in the extrusion direction.

Accordingly, it is possible to form the structure in a variety of shapes, and it is possible to improve the design freedom.

The display apparatus according to an embodiment of the present disclosure includes a panel module which includes a display on which an image is displayed; and a bezel which maintains a peripheral portion of the panel module, in which the bezel is formed from a molded product which is formed using profile extrusion so as to have a folding notch open in a direction orthogonal to an extrusion direction, each portion of an open edge of the folding notch is formed as a first matching portion and a second matching portion which are separate or continuous in the extrusion direction, and the molded product is folded such that the first matching portion and the second matching portion face each other, thereby forming the bezel.

Accordingly, since the molded product configuring the structure is formed using extrusion and not injection molding, it is possible to reduce the manufacturing cost of the display apparatus.

In addition, even when the shape of the structure is modified, it is not necessary to manufacture a new molding die appropriate for the structure, as is in the injection molding, and it is possible to improve the design freedom accordingly.

The method of molding a structure according to an embodiment of the present disclosure includes forming a molded product using profile extrusion; forming a folding notch on the molded product, where the folding notch is open in a direction orthogonal to an extrusion direction and each portion of an open edge of the folding notch is a first matching portion and a second matching portion which are separate or continuous in the extrusion direction; and folding the molded product such that the first matching portion and the second matching portion face each other, thereby forming the structure.

Accordingly, since the molded product configuring the structure is formed using extrusion and not injection molding, it is possible to reduce the manufacturing cost of the structure.

In addition, even when the shape of the structure is modified, it is not necessary to manufacture a new molding die appropriate for the structure, as is in the injection molding, and it is possible to improve the design freedom accordingly.

### BRIEF DESCRIPTION OF THE DRAWINGS

FIG. 1, along with FIGS. 2 to 21, illustrates an embodiment of the present disclosure and is a schematic perspective view of the display apparatus.

FIG. 2 is a schematic perspective view of the display apparatus shown in a state when viewed from the opposite side to that in FIG. 1.

FIG. 3 is an enlarged cross-sectional view of the bezel.

FIG. 4 is a front view of the molded product.

FIG. 5 is a front view showing a state in which the folding notch is formed in the molded product.

FIG. 6 is an enlarged front view showing the portion in which the folding notch is formed in the molded product.

FIG. 7 is an enlarged front view showing the state in which the molded product is folded.

FIG. 8 is an enlarged front view showing the state in which the molded product is folded to form a bezel.

FIG. 9 is an enlarged perspective view showing the state prior to the fixing member being fixed to the bezel.

FIG. 10 is an enlarged perspective view showing the state in which the fixing member is fixed to the bezel.

FIG. 11 is a front view showing an example in which two folding notches are formed in the molded product.

FIG. 12 is a front view showing an example in which the molded product which has two folding notches is folded to form a bezel.

FIG. 13 is an enlarged front view showing an example in which a small opening having a curved periphery is formed.

FIG. 14 is an enlarged front view showing a state in which a molded product, in which a small opening having a curved periphery is formed, is folded.

FIG. 15 is an enlarged front view showing an example in which the first matching portion and the second matching portion are formed by two straight line shaped portions.

FIG. 16 is an enlarged front view showing an example in which the first matching portion and the second matching portion are formed in a curved line shape.

FIG. 17, along with FIGS. 18 to 21, shows an example in which a bezel is configured by joining molded products of different widths, and is an enlarged front view showing a state prior to the molded product being folded.

FIG. 18 is an enlarged front view showing the state in which the molded product is folded.

FIG. 19 is an enlarged cross-sectional perspective view showing a state prior to the molded products being joined to each other.

FIG. 20 is an enlarged cross-sectional perspective view showing a state in which the first joint portion of the fixing member is joined to one of the molded products.

FIG. 21 is an enlarged cross-sectional perspective view showing a state in which the second joint portion of the fixing member is joined to another of the molded products.

### DETAILED DESCRIPTION OF EMBODIMENTS

The best mode for realizing a structure, a display apparatus and a method of molding the structure according to an embodiment of the present disclosure is described below in accordance with the attached drawings.

The best mode shown below applies the display apparatus of the embodiment of the present disclosure to a television receiver including a flat display panel, the structure of the embodiment of the present disclosure to a bezel of the television receiver, and the method of molding the structure of the embodiment of the present disclosure to the method of molding the bezel.

Furthermore, the application scope of the display apparatus, the structure, and the method of molding the structure of the embodiment of the present disclosure is not limited to a television receiver including a flat display panel, a bezel of the television receiver, and the method of molding the bezel, respectively.

The application scope of the display apparatus of the embodiment of the present disclosure can be widely applied to various display apparatuses, such as a monitor used in other various television receivers, personal computers and the like, regardless of the type of the display.

In addition, the application scope of the structure and the method of molding the structure of the embodiment of the present disclosure can be widely applied to various structures formed using an extrusion apparatus and to the methods of molding the structures.

### Configuration of Display Apparatus

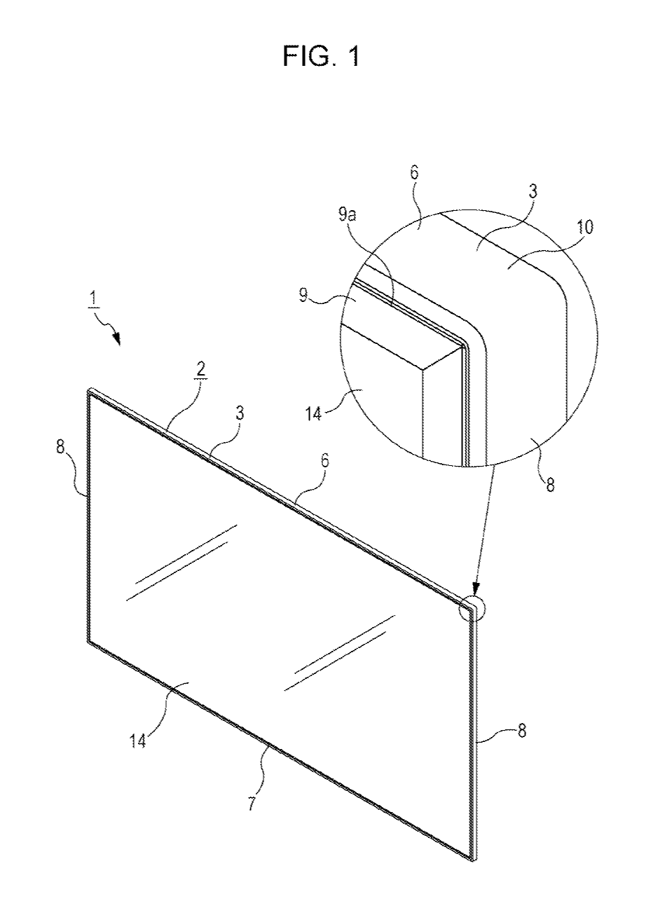

For example, the display apparatus (the television receiver) 1 is formed in a substantially rectangular shape, which is horizontally long and planar, and the various necessary portions are disposed in the housing 2 (refer to FIG. 1). For example, the display apparatus 1 is maintained by a stand (not shown).

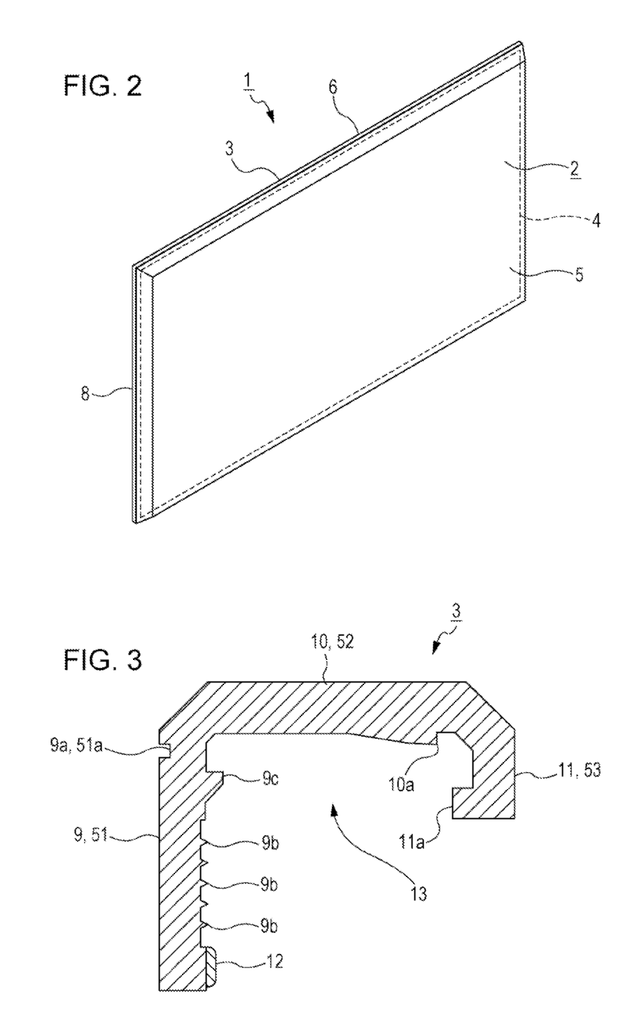

The housing 2 includes a bezel 3 positioned on the front side, a back chassis 4 positioned on the rear side, and a rear cover 5 attached to the rear face side of the back chassis 4 (refer to FIGS. 1 and 2).

For example, the bezel 3 is formed in a substantially rectangular frame shape, and includes horizontal portions 6 and 7 positioned at the top and the bottom, and vertical portions 8 and 8 positioned at the left and the right. The horizontal portions 6 and 7 are provided to extend in the horizontal direction, and the vertical portions 8 and 8 are provided to extend in the vertical direction.

The bezel 3 is provided as a structure which is formed by folding the molded product, described below and formed using profile extrusion, into a predetermined shape. For example, the bezel 3 is formed from a resin material, a metal material, a ceramic material or the like. The bezel 3 includes a front face portion (a first face portion) 9, a circumferential face portion (a second face portion) 10 and a rear face portion (a third face portion) 11 (refer to FIG. 3).

A groove portion 9a which extends in the circumferential direction is formed in the peripheral portion of the front face of the front face portion 9 (refer to FIGS. 1 and 3). Welding ribs 9b, 9b, . . . which extend in the circumferential direction are formed on the rear face of the front face portion 9 so as to be separated from each other in the interior-exterior direction (vertically or horizontally). On the rear face of the front face portion 9, an engaging protrusion portion 9c which protrudes to the rear is provided on the outside of the welding ribs 9b, 9b, . . . so as to extend in the circumferential direction.

Furthermore, due to the groove portion 9a being formed in a position near the periphery of the front face portion 9 of the bezel 3, the width of the front face portion 9 appears to be smaller than the actual width when the bezel 3 is viewed from the outside. Therefore, the bezel 3 appears to be small and the design of the display apparatus 1 is improved.

A cushion 12 which extends in the circumferential direction is provided in the inner peripheral portion of the rear face of the front face portion 9. Furthermore, it is possible to form the cushion 12 by extruding a soft, different material such as rubber at the same time as the resin material or the like which is the bezel 3 material.

The circumferential face portion 10 is provided so as to protrude from the peripheral portion of the front face portion 9 to the rear. An engaging protrusion portion 10a which protrudes inward is provided in a position near the rear end of the circumferential face portion 10.

The rear face portion 11 is provided so as to protrude inward from the rear end portion of the circumferential face portion 10. The engaging beam 11a which protrudes forward is provided in the inner peripheral portion of the rear face portion 11.

A maintaining space 13 is formed by the peripheral portion of the front face portion 9, the circumferential face portion 10 and the rear face portion 11. The maintaining space 13 maintains a member (not shown) or the like which is disposed on the peripheral portion of the panel module 14 or on the peripheral side of the panel module 14 (refer to FIG. 1).

A display on which an image is displayed and a diffuser plate which diffuses light incident to the display, a plurality of optical sheets which each exhibit a predetermined function in relation to the light incident to the display, a light source which functions as a back light, a light guide plate which guides the light in a predetermined direction, a maintaining bracket and the like are disposed to form the panel module 14.

In a state in which the panel module 14 is maintained in the bezel 3, the front face of the panel module 14 is pressed against the cushion 12, thereby the panel module 14 is protected by the cushion 12.

### Method of Molding Structure

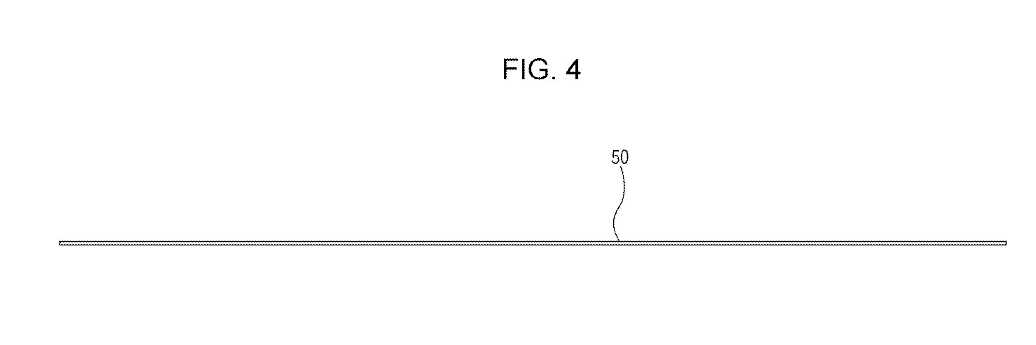

The method of molding the bezel 3 provided as the structure is described below (refer to FIGS. 4 to 10).

First, the molded product 50 is formed using extrusion prior to being formed as the structure (refer to FIG. 4). Since the molded product 50 is formed using an extrusion apparatus, the cross-sectional shape is the same in all positions, and the molded product 50 is formed in a shape that extends in one direction.

The cross-sectional shape of the molded product 50 is the same as the cross-sectional shape shown in FIG. 3. The molded product 50 is formed from a first portion 51, a second portion 52 and a third portion 53, which are respectively formed as the front face portion 9, the circumferential face portion 10 and the rear face portion 11. Accordingly, a groove portion 51a is formed in the first portion 51 as the groove portion 9a.

Next, folding notches 54, 54, . . . are formed at respective predetermined positions in the first portion 51 of the molded product 50 using machining, for example. In addition, notches (not shown) are also formed in the third portion 53 at the same positions as the positions at which the folding notches 54, 54, . . . are formed using machining, for example.

For example, in the molded product 50, four of the folding notches 54, 54, . . . are formed separated in the longitudinal direction, thereby the molded product 50 is divided into five portions by the folding notches 54, 54, . . . formed in the first portion 51 and each of the notches formed in the third portion 53, for example.

The five portions are as follows: a base portion 55 formed as the horizontal portion 6; central portions 56 and 56 which are continuous with both sides of the base portion 55, and are respectively formed as the vertical portions 8 and 8; and end portions 57 and 57 which are respectively continuous with both sides of the vertical portions 8 and 8, and are formed as the horizontal portion 7. In addition, the base portion 55 is longer than the central portion 56, and the total length of the end portions 57 and 57 is approximately the same as the length of the base portion 55.

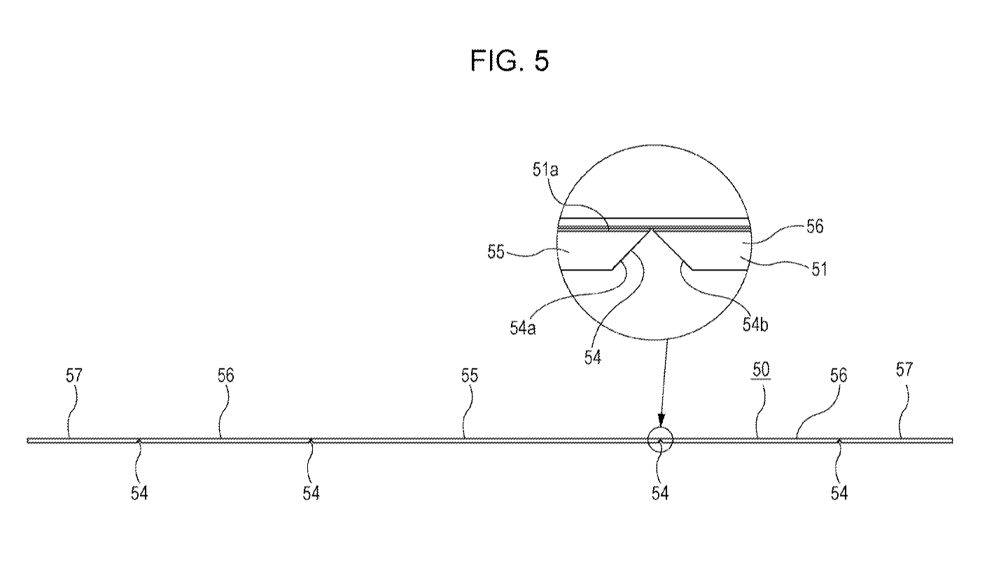

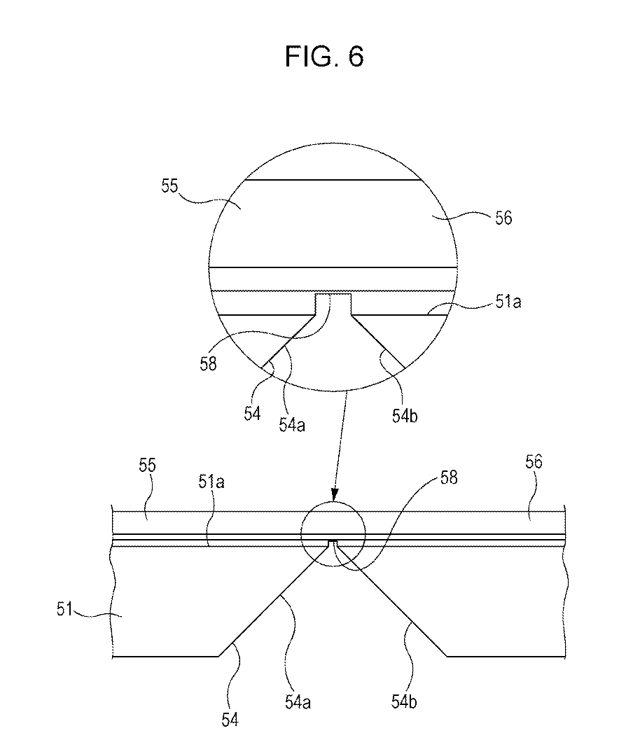

The further from the second portion 52, the wider the width of the folding notch 54 becomes, and the folding notch 54 is formed in a substantially isosceles triangle shape with a vertical angle of 45° (refer to FIGS. 5 and 6). Accordingly, the open edge of the folding notch 54 is configured to include two portions which are inclined in relation to the first portion 51 in the longitudinal direction (the extrusion direction of the extrusion apparatus of the molded product 50), one of which is formed as the first matching portion 54a, and the other is formed as the second matching portion 54b. The further from the second portion 52, the more the first matching portion 54a and the second matching portion 54b separate from each other. The first matching portion 54a and the second matching portion 54b are substantially V-shaped.

Small openings 58, 58, . . . are formed in the first portion 51 in communication with the folding notches 54, 54, . . . , respectively. Furthermore, the small opening 58 may also be formed at the same time as the formation of the folding notch 54, and may also be formed after the formation of the folding notch 54. In addition, it is also possible to form the small opening 58 first, and form the folding notch 54 after the formation of the small opening 58.

For example, the small opening 58 is formed in a substantially rectangular shape, is penetrated in the thickness direction of the first portion 51, and both ends in the circumferential direction are continuous with each end of the second portion 52 side of the first matching portion 54a and the second matching portion 54b, respectively. The small opening 58 is formed in the groove portion 51a.

Furthermore, a small opening similar to the small opening 58 may also be formed in the third portion 53 to be continuous with the notch.

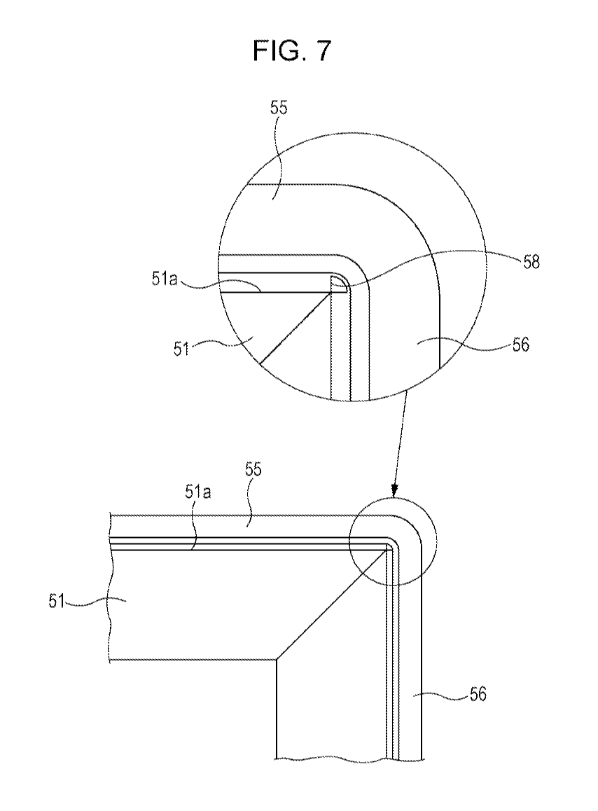

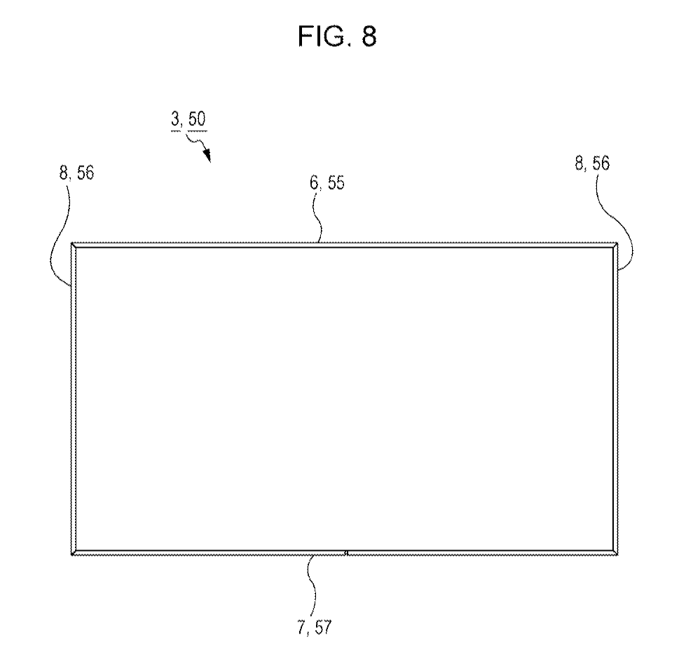

Next, each portion is folded by 90° in the portions in which the folding notches 54, 54, . . . are formed (refer to FIGS. 7 and 8). In other words, the central portions 56 and 56 are each folded by 90° in relation to the base portion 55, and the end portions 57 and 57 are each folded by 90° in relation to the central portions 56 and 56.

Due to each portion being folded in this manner, the first matching portions 54a, 54a, . . . and the second matching portions 54b, 54b, . . . of the folding notches 54, 54, . . . , face each other (refer to FIG. 7).

As described above, the central portions 56 and 56 are each folded by 90° in relation to the base portion 55, and the end portions 57 and 57 are each folded by 90° in relation to the central portions 56 and 56. Therefore, the bezel 3 of a frame shape is formed (refer to FIG. 8). At this time, the end portions 57 and 57 are positioned corresponding to each of the tip end faces in a proximal or abutting state.

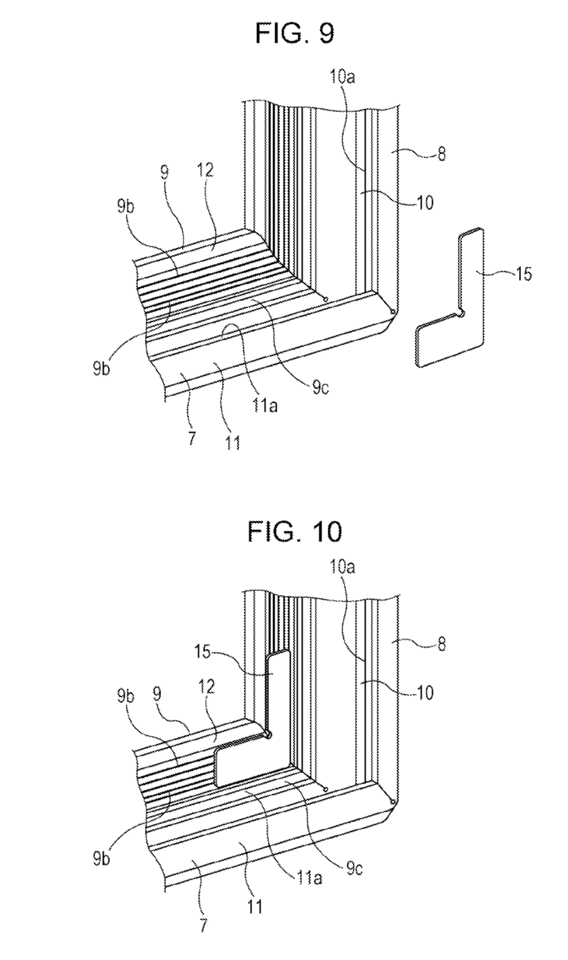

In a state in which the bezel 3 is formed by each portion being folded as described above, it is desirable that fixing members 15, 15, . . . are joined to the portions at the four locations between the central portions 56 and 56 and the base portion 55, and, between the end portions 57 and 57 and the central portions 56 and 56, such that each portion is fixed (refer to FIGS. 9 and 10).

For example, the fixing member 15 is a plate-shaped metal member formed in an L-shape, and is joined to the rear face of the front face portion 9. Examples of methods of joining the fixing member 15 include welding, screw fastening and adhesion.

Furthermore, it is possible to use a laminated steel plate, in which a resin material is laminated onto one face of a plate-shaped metal material, as the fixing member 15. When such a laminated steel plate is used, in a case in which the bezel 3 is formed from a resin material, it is possible to join the resin material of the laminated steel plate to the bezel 3 using ultrasonic welding. In this case, the welding ribs 9b, 9b, . . . are melted by pressing the fixing member 15 against the welding ribs 9b, 9b, . . . and welding them. Therefore, it is possible to secure favorable joining properties. In addition, by performing ultrasonic welding, it is possible to join the fixing member 15 to the bezel 3 in a short time of less than one second.

As described above, in a state in which each portion is folded and the first matching portion 54a and the second matching portion 54b face each other, there is a concern that a so-called bulge will occur in the surface of the structure. The bulge in the surface of the structure is the bulging of the portions which are folded, in particular, the end portion of the second portion 52 side, at which the first matching portion 54a and the second matching portion 54b approach each other.

However, since the small opening 58 which communicates with the folding notch 54 is formed in the first portion 51, the surface of the structure which is to protrude to the outside due to folding is positioned in the small opening 58, and it is possible to reduce the bulging of the surface of the structure.

In addition, when each of the portions is folded, the end portions of the second portion 52 side of the first matching portion 54a and the second matching portion 54b are deformed. There is a concern that the degree of deformation in these portions is inconsistent according to the processing precision of the folding notch 54. However, since the small opening 58 is formed in the portion at which deformation occurs, the irregularities during the deformation are absorbed by the small opening 58, and it is possible to secure an appropriate folding state of each of the portions.

Furthermore, the groove portion 51a (9a) which extends in the longitudinal direction (the extrusion direction) is formed in the molded product 50. Since the small opening 58 is formed in the groove portion 51a, even when the surface of the structure bulges, the bulge is present in the groove portion 51a, the state of the bulge of the surface of the structure is not obvious from the outside, and it is possible to improve the visual properties of the bezel 3 and the display apparatus 1.

Yet furthermore, since the small opening 58 is present in the groove portion 51a, the small opening 58 is not obvious in a state in which each of the portions is folded and the first matching portion 54a and the second matching portion 54b face each other. Therefore, it is possible to further improve the visual properties of the bezel 3 and the display apparatus 1.

Furthermore, the first matching portion 54a and the second matching portion 54b of the folding notch 54 formed in the molded product 50 are both formed in a straight-line shape. Accordingly, it is easy to form the folding notch 54, the processing precision of the folding notch 54 is high, and when the first matching portion 54a and the second matching portion 54b face each other, a gap is not easily formed therebetween. Therefore, it is possible to form the bezel 3 with a high molding precision.

In addition, the first matching portion 54a and the second matching portion 54b are substantially formed in a V-shape. Therefore, the formation of the folding notch 54 is even easier, the processing precision of the folding notch 54 is also higher, and it is possible to form the bezel 3 with an even higher molding precision.

Furthermore, as described above, a plurality of the folding notches 54, 54, . . . are formed in the longitudinal direction of the molded product 50. Therefore, it is possible to form the same number of folding locations as the number of the folding notches 54, 54, . . . , it is possible to form the structure in a variety of shapes, and it is possible to improve the design freedom.

In addition, the bezel 3 is formed such that the first portion 51 (the front face portion 9) and the second portion 52 (the circumferential face portion 10) are orthogonal to each other. The second portion 52 (the circumferential face portion 10) and the third portion 53 (the rear face portion 11) are formed orthogonal to each other, and the folding notches 54, 54, . . . are formed in the first portion 51.

Accordingly, the bezel 3 includes orthogonal portions, the folding notches 54, 54, . . . are formed only in the first face portion 51, and the notches or the like are not formed on the second portion 52 and the third portion 53. Therefore, it is possible to secure high rigidity in the entirety of the bezel 3.

### Other Examples

An example was described above in which four of the folding notches 54, 54, . . . are formed in the molded product 50, and the molded product 50 is divided into the five portions of the base portion 55, the central portions 56 and 56 and the end portions 57 and 57. However, the number by which the molded product 50 is divided is not limited to five, and the number by which the molded product 50 is divided is arbitrary.

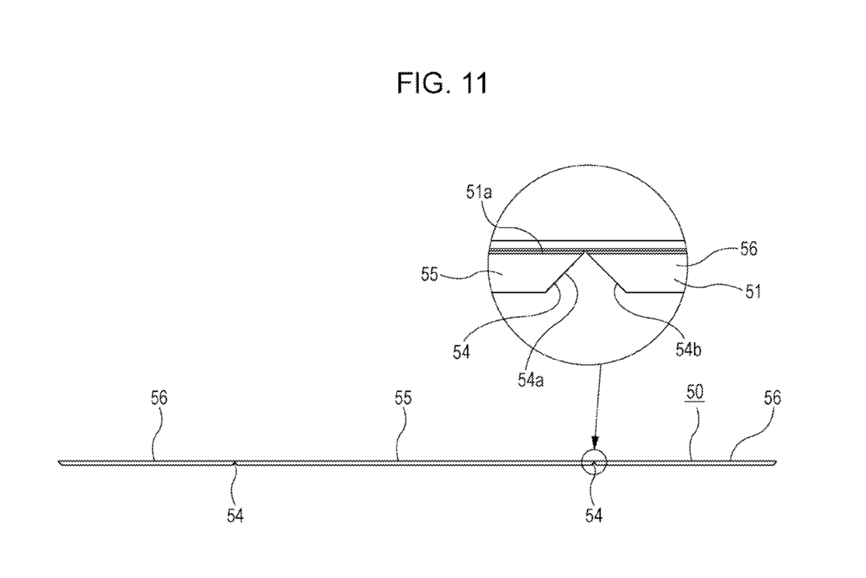

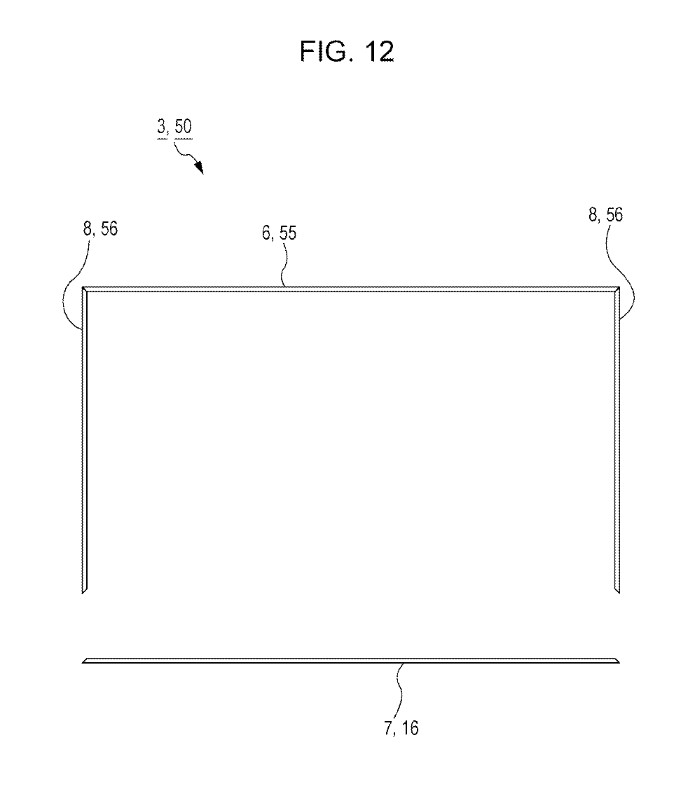

For example, two of the folding notches 54 and 54 are formed in the molded product 50, and the molded product 50 may also be divided into the three portions of the base portion 55 and the central portions 56 and 56 (refer to FIGS. 11 and 12). In this case, the horizontal portion 6 and the vertical portions 8 and 8 are respectively formed by the base portion 55 and the central portions 56 and 56, and using another member 16 formed as the horizontal portion 7, it is possible to form the bezel 3 by joining both end portions of the members 16 and 16 to the central portions 56 and 56, respectively.

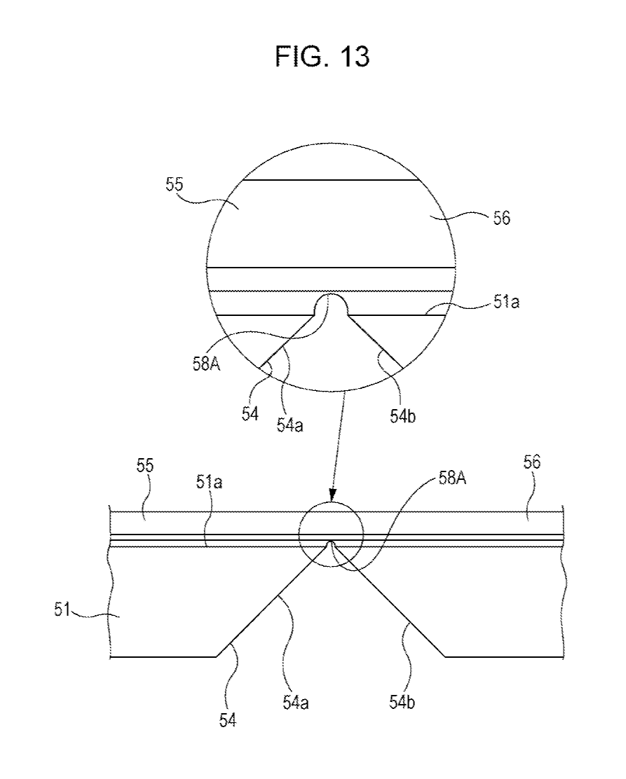

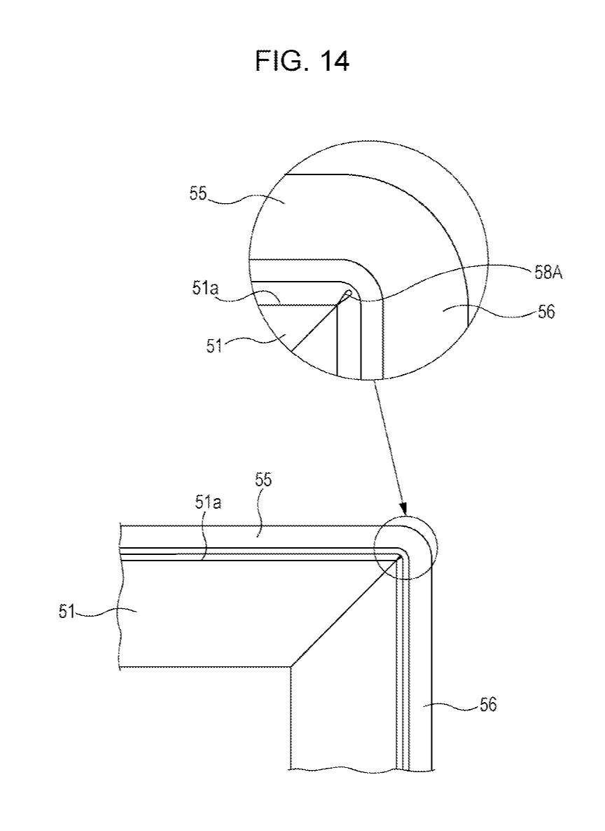

In addition, the small opening 58 formed in a rectangular shape was shown above as an example, however, a small opening 58A may also be formed with a curved periphery (refer to FIGS. 13 and 14). For example, the small opening 58A is formed in a substantially semicircular shape.

Since there are no corner portions in the periphery of the small opening 58A due to the small opening 58A being formed with a curved periphery in this manner, stress is not apt to concentrate in the periphery of the small opening 58A during the folding of each portion, and it is possible to prevent the occurrence of cracks in the bezel 3.

Furthermore, the folding notch 54 including the first matching portion 54a and the second matching portion 54b, each of which having a straight-line shape, was exemplified above, however, it is possible to form the folding notch 54 in such shapes as are described below.

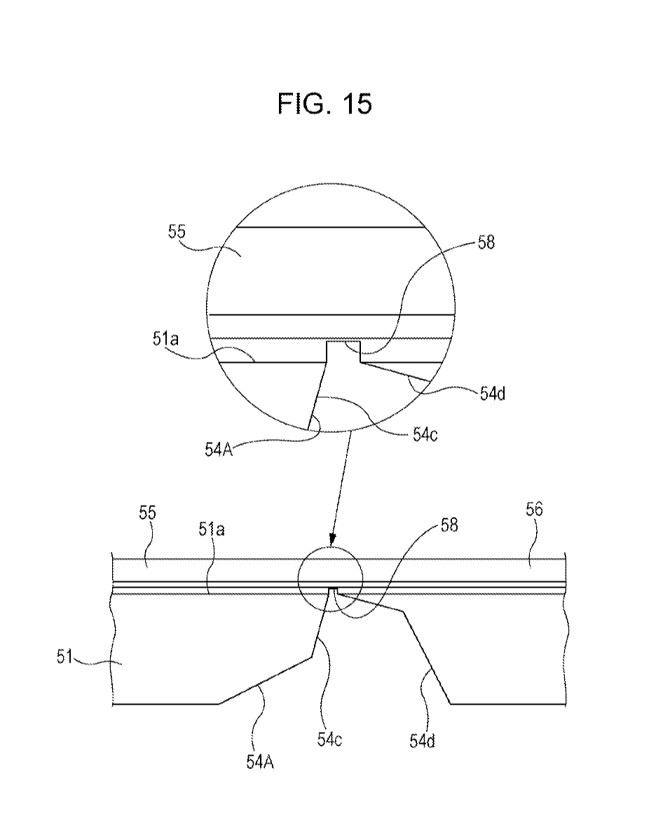

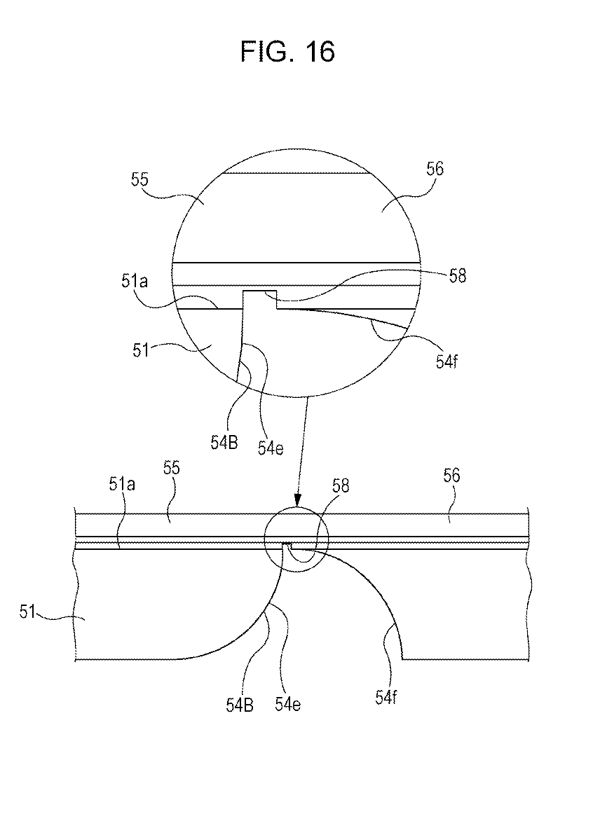

For example, a folding notch 54A including a first matching portion 54c and a second matching portion 54d, which are respectively configured by a plurality of straight lines, may also be formed (refer to FIG. 15). In addition, a folding notch 54B including a first matching portion 54e and a second matching portion 54f of a curved line shape may also be formed (refer to FIG. 16).

In addition, the first matching portion and the second matching portion may also be configured by an arbitrary combination of straight lines and curved lines, and the number of straight lines and curved lines is also arbitrary.

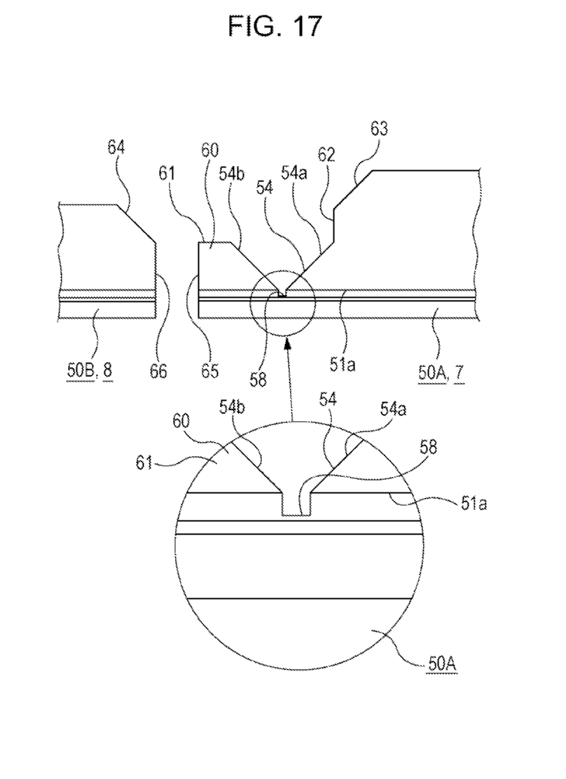

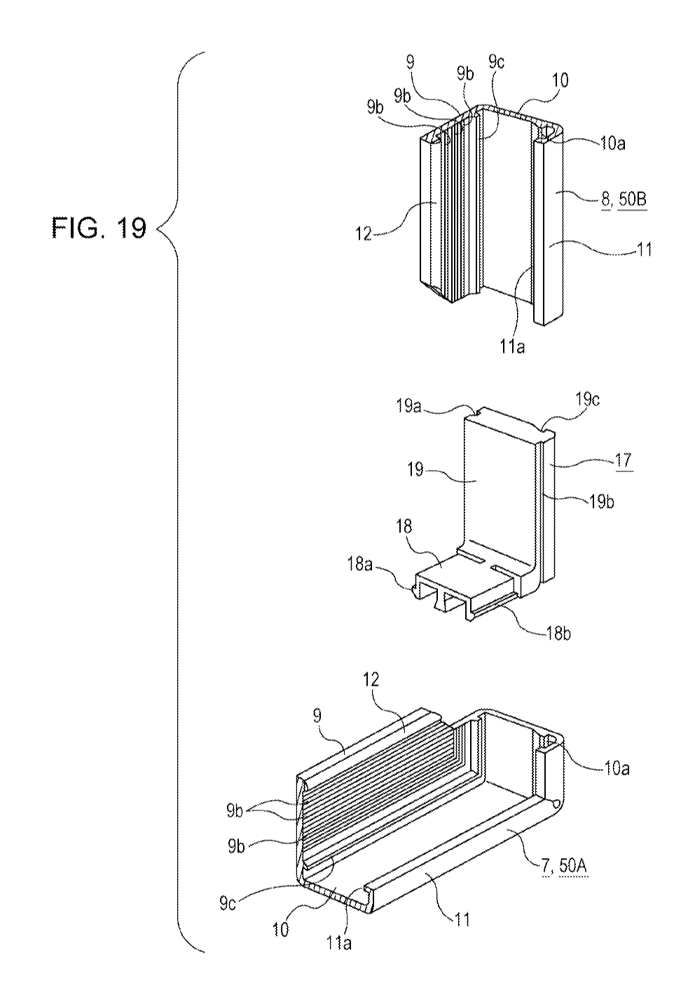

Next, a example is described in which the bezel 3 is formed in which the widths of the horizontal portions 6 and 7 and the vertical portions 8 and 8 differ (refer to FIGS. 17 to 21).

In the example in which the widths differ, for example, the horizontal portions 6 and 7 are formed by being folded, and the vertical portions 8 and 8 are formed without being folded. Furthermore, in contrast, the horizontal portions 6 and 7 may also be formed without being folded, and the vertical portions 8 and 8 may also be formed by being folded. However, the example in which the horizontal portions 6 and 7 are formed by being folded is shown.

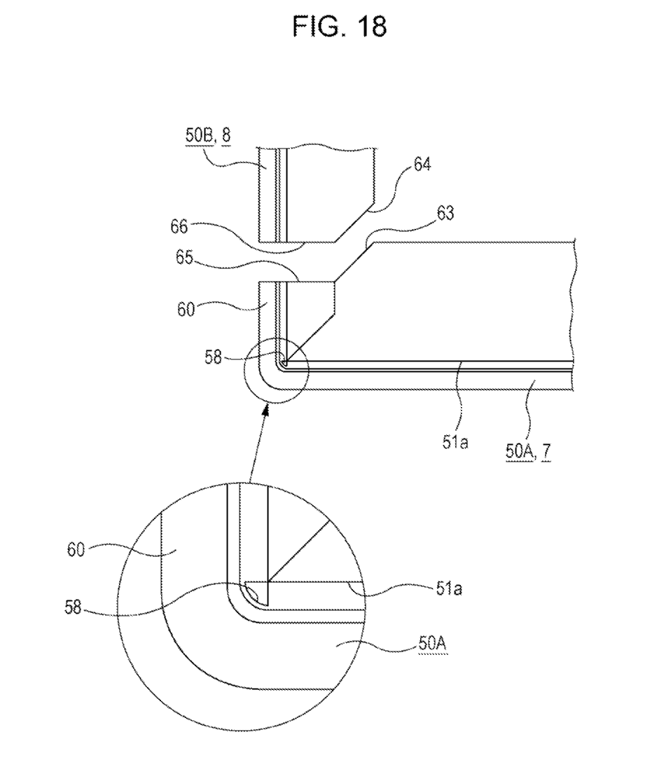

First, the molded products 50A and 50A and the molded products 50B and 50B are each formed using extrusion prior to being formed as the structure (refer to FIGS. 17 and 18).

The horizontal portions 6 and 7 are respectively formed from the molded products 50A and 50A, and the vertical portions 8 and 8 are configured by the molded products 50B and 50B. Furthermore, since the molded product 50A and the molded product 50B are configured by the first portion 51, the second portion 52 and the third portion 53 in the same manner as the molded product 50 and have the same general structure, only the configuration which differs from the molded product 50 will be described in detail below.

The width of the molded product 50B is smaller than the width in the longitudinal direction of the molded product 50A excluding both end portions.

The folding notches 54 and 54 are formed in positions near both ends of the molded product 50A in the longitudinal direction, respectively. The end portion closer to the outside than the folding notch 54 in the longitudinal direction of the molded product 50A is provided as a narrow width portion 60 which has a smaller width than the other portions. In addition, a contact edge 61, which is continuous with the second matching portion 54b and extends in the horizontal direction, is formed in the narrow width portion 60.

A contact edge 62 which extends in the vertical direction is formed on a portion which is continuous with the inside of the folding notch 54 in the longitudinal direction of the molded product 50A. The contact edge 62 is the same length as the contact edge 61.

An inclined edge 63 is formed on the molded product 50A to be continuous with the contact edge 62.

An inclined edge 64 is formed on both end portions in the longitudinal direction of the molded product 50B. The inclined edge 64 is formed at the same length as the inclined edge 63 of the molded product 50A.

In the molded product 50A, the narrow width portion 60 is folded by 90° in the portion at which the folding notch 54 is formed (refer to FIG. 18).

By folding the narrow width portion 60, the first matching portion 54a and the second matching portion 54b of the folding notch 54 face each other, and the contact edge 61 and the contact edge 62 face each other.

Next, the molded product 50A and the molded product 50B are joined and the bezel 3 is formed. When the molded product 50A and the molded product 50B are joined, the inclined edge 63 and the inclined edge 64 face each other, and the tip edge 65 of the narrow width portion 60 and the tip edge 66 of the molded product 50B face each other.

In a state in which the molded product 50A and the molded product 50B are joined, it is desirable, for example, that both be fixed using a fixing unit such as the fixing member 15.

Furthermore, it is also possible to use a fixing member 17 such as that described below instead of the fixing member 15. Furthermore, an example is shown below in which the horizontal portion 7 and the vertical portion 8 are fixed by the fixing member 17.

The fixing member 17 is formed from a first joint portion 18 which extends horizontally and a second joint portion 19 which is continuous with one end portion of the first joint portion 18 and extends vertically. The fixing member 17 is formed such that the entirety thereof is L-shaped.

Engaging portions 18a and 18b are provided on the first joint portion 18 so as to be elastically deformable. The engaging portions 18a and 18b each extend horizontally to both end portions at the front and the rear of the first joint portion 18.

Engaging concave portions 19a, 19b and 19c are formed on the second joint portion 19. The engaging concave portions 19a, 19b and 19c each extend vertically to both end portions at the front and the rear of the second joint portion 19.

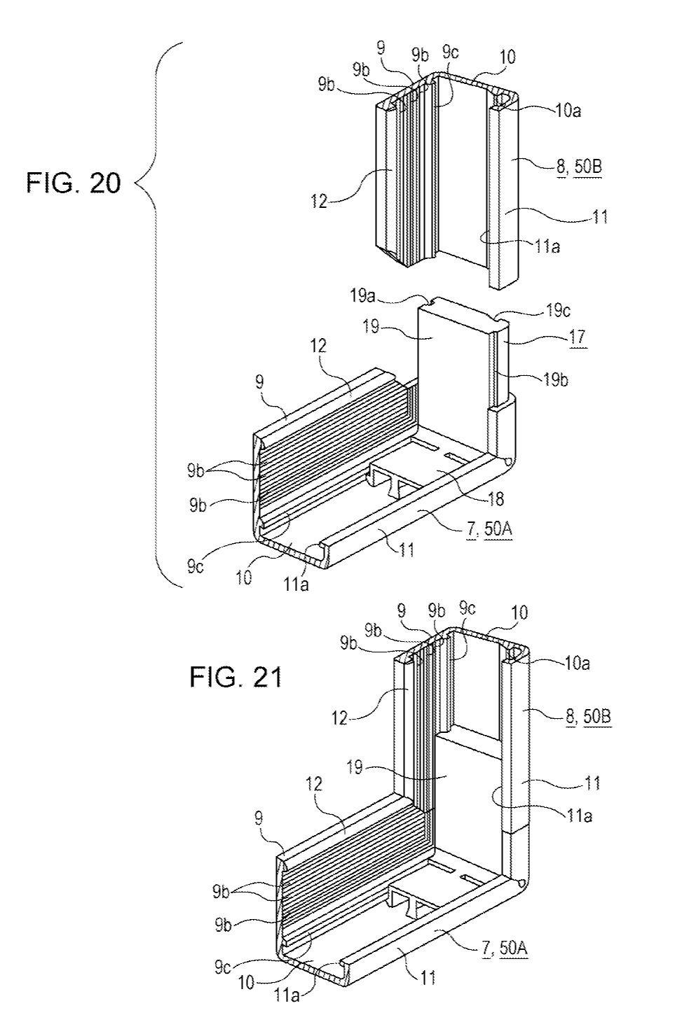

In the fixing member 17 configured as described above, first, the engaging portions 18a and 18b are joined to the engaging protrusion portion 9c of the horizontal portion 6 and the engaging beam 11a, respectively (refer to FIG. 20). The engaging portions 18a and 18b are engaged with the engaging protrusion portion 9c and the engaging beam 11a as follows. The first joint portion 18 is inserted into the maintaining space 13 of the horizontal portion 6 from above, and during the insertion, the engaging portions 18a and 18b are caused to slide and elastically deform on the engaging protrusion portion 9c and the engaging beam 11a. Subsequently, the engaging portions 18a and 18b return to their original shapes through elasticity.

In this manner, the engaging portions 18a and 18b are engaged with the engaging protrusion portion 9c and the engaging beam 11a due to the first joint portion 18 being inserted into the maintaining space 13 of the horizontal portion 6. Therefore, the operation is simple and it is possible to improve the operability.

Next, the vertical portion 8 is moved downward, the vertical portion 8 is caused to slide in relation to the second joint portion 19, and the engaging concave portions 19a, 19b and 19c are engaged with the engaging protrusion portion 9c, the engaging beam 11a and the engaging protrusion portion 10a, respectively.

In this manner, the engaging concave portions 19a, 19b and 19c are engaged with the engaging protrusion portion 9c, the engaging beam 11a and the engaging protrusion portion 10a due to the vertical portion 8 being caused to slide in relation to the second joint portion 19. Therefore, the operation is simple and it is possible to improve the operability.

Furthermore, in contrast with the above description, the second joint portion 19 may also be joined to the vertical portion 8 by moving the horizontal portion 7 to which the fixing member 17 is joined upward and sliding the second joint portion 19 in relation to the vertical portion 8.

As described above, the engaging portions 18a and 18b are engaged with the engaging protrusion portion 9c and the engaging beam 11a, respectively, and the engaging concave portions 19a, 19b and 19c are engaged with the engaging protrusion portion 9c, the engaging beam 11a and the engaging protrusion portion 10a, respectively. Therefore, the horizontal portion 7 and the vertical portion 8 are joined and fixed by the fixing member 17.

In a state in which the horizontal portions 6 and 7 and the vertical portions 8 and 8 are fixed by the fixing members 17, 17, . . . , the fixing members 17, 17, . . . are disposed in a state of being interlocked with the inside of the joint portions of the horizontal portions 6 and 7 and the vertical portions 8 and 8. Therefore, it is possible to improve the rigidity of the bezel 3.

### Conclusion

As described above, the folding notches 54 open in a direction orthogonal to the extrusion direction (the longitudinal direction) are formed on the molded products 50 and 50A which are formed using profile extrusion, and the molded products 50 and 50A are folded, the first matching portion 54a and the second matching portion 54b face each other, and the bezel 3 is formed.

Accordingly, since the molded products 50, 50A and 50B configuring the bezel 3 are formed using extrusion and not injection molding, it is possible to reduce the manufacturing cost of the bezel 3.

In addition, even when the shape of the bezel 3 is modified, it is not necessary to manufacture a new molding die appropriate for the bezel 3, as is in the injection molding, and it is possible to improve the design freedom accordingly.

Furthermore, in the formation of the structure using a molding die, in order to facilitate the pushing out of the structure using an ejector pin, it is necessary to form a draft angle in the molding die. Accordingly, the structure is thick and becomes large.

However, in the display apparatus 1, since the bezel 3 is formed using extrusion, it is not necessary to form a draft angle. Accordingly, it is possible to miniaturize the bezel 3 and the display apparatus 1.

Yet furthermore, it is not necessary to form the undercut portion using a slider as in the injection molding, and it is possible to form the undercut portion without bringing about a rise in the manufacturing cost.

In addition, by forming the bezel 3 using extrusion, it is also possible to perform multicolor molding or decoration by applying a film. Therefore, it is possible to improve the design freedom and the design of the bezel 3.

### Present Disclosure

The present disclosure may also adopt configurations such as the following.

(1) A structure in which a folding notch, which is open in a direction orthogonal to an extrusion direction, is formed on a molded product formed using profile extrusion, each portion of an open edge of the folding notch is formed as a first matching portion and a second matching portion which are separate or continuous in the extrusion direction, and the molded product is folded such that the first matching portion and the second matching portion face each other.

(2) The structure according to (1), in which the molded product is formed with a small opening in communication with the folding notch, and both ends of the small opening in a circumferential direction are continuous with each end of the first matching portion and the second matching portion, respectively.

(3) The structure according to (2), in which a groove portion which extends in the extrusion direction is formed in the molded product, and the small opening is formed in the groove portion.

(4) The structure according to (2) or (3), in which a periphery of the small opening is formed in a curved line shape.

(5) The structure according to any one of (2) to (4), in which both the first matching portion and the second matching portion are formed in a straight line shape.

(6) The structure according to (5), in which the first matching portion and the second matching portion are formed in a V-shape.

(7) The structure according to any one of (2) to (6), in which a first face portion and a second face portion which each extend in the extrusion direction orthogonal to each other are provided, and the folding notch is formed in the first face portion.

(8) The structure according to any one of (2) to (7), in which a plurality of the folding notches is formed in the extrusion direction.

(9) A display apparatus including a panel module which includes a display on which an image is displayed; and a bezel which maintains a peripheral portion of the panel module, in which the bezel is formed from a molded product which is formed using profile extrusion so as to have a folding notch open in a direction orthogonal to an extrusion direction, each portion of an open edge of the folding notch is formed as a first matching portion and a second matching portion which are separate or continuous in the extrusion direction, and the molded product is folded such that the first matching portion and the second matching portion face each other, thereby forming the bezel.

(10) A method of molding a structure including forming a molded product using profile extrusion; forming a folding notch on the molded product, where the folding notch is open in a direction orthogonal to an extrusion direction and each portion of an open edge of the folding notch is a first matching portion and a second matching portion which are separate or continuous in the extrusion direction, and folding the molded product such that the first matching portion and the second matching portion face each other, thereby forming the structure.

The specific forms and structures of each portion shown in the best mode for realizing the technology described above all merely show specific examples of embodiments of the present disclosure, and the technical scope of the present disclosure is not to be interpreted as limited according to such examples.

The present disclosure contains subject matter related to that disclosed in Japanese Priority Patent Application JP 2012-185690 filed in the Japan Patent Office on Aug. 24, 2012, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A structure,
wherein a folding notch, which is open in a direction orthogonal to an extrusion direction, is formed on a molded product formed using profile extrusion,
each portion of an open edge of the folding notch is formed as a first matching portion and a second matching portion which are separate or continuous in the extrusion direction, and
the molded product is folded such that the first matching portion and the second matching portion face each other.

2. The structure according to claim 1,
wherein the molded product is formed with a small opening in communication with the folding notch, and
both ends of the small opening in a circumferential direction are continuous with each end of the first matching portion and the second matching portion, respectively.

3. The structure according to claim 2,
wherein a groove portion which extends in the extrusion direction is formed in the molded product, and
the small opening is formed in the groove portion.

4. The structure according to claim 2, wherein a periphery of the small opening is formed in a curved line shape.

5. The structure according to claim 1, wherein both the first matching portion and the second matching portion are formed in a straight line shape.

6. The structure according to claim 5, wherein the first matching portion and the second matching portion are formed in a V-shape.

7. The structure according to claim 1,
wherein a first face portion and a second face portion which each extend in the extrusion direction orthogonal to each other are provided, and
the folding notch is formed in the first face portion.

8. The structure according to claim 1, wherein a plurality of the folding notches is formed in the extrusion direction.

9. A display apparatus comprising:
a panel module which includes a display on which an image is displayed; and
a bezel which maintains a peripheral portion of the panel module,
wherein the bezel is formed from a molded product which is formed using profile extrusion so as to have a folding notch open in a direction orthogonal to an extrusion direction,
each portion of an open edge of the folding notch is formed as a first matching portion and a second matching portion which are separate or continuous in the extrusion direction, and
the molded product is folded such that the first matching portion and the second matching portion face each other, thereby forming the bezel.

10. A method of molding a structure comprising:
forming a molded product using profile extrusion;
forming a folding notch on the molded product, where the folding notch is open in a direction orthogonal to an extrusion direction and each portion of an open edge of the folding notch is a first matching portion and a second matching portion which are separate or continuous in the extrusion direction; and
folding the molded product such that the first matching portion and the second matching portion face each other, thereby forming the structure.
